(19) United States
(12) Patent Application Publication
(10) Pub. No.: US 2006/0103470 A1
(43) Pub. Date: May 18, 2006

(54) Power amplifier module

(75) Inventor: Ichiro Kato, Kosai-shi (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/274,153

(22) Filed: Nov. 16, 2005

(30) Foreign Application Priority Data
Nov. 17, 2004 (JP) 2004-332527

(51) Int. Cl. H03F 3/14

(52) U.S. Cl. 330/307

(57) ABSTRACT

A semiconductor chip is wired with a bonding wire on a conductor pattern formed on a substrate, the bonding wire is connected to a bonding position at a midpoint of a distributed constant line formed by the conductor pattern and divides the line into a first inductor and a second inductor, and matching of handled frequencies or an output load is performed. With this configuration, power amplifier modules for amplifying given frequency bands can be manufactured using a common substrate.

### FIELD OF THE INVENTION

The present invention relates to a power amplifier module.

### BACKGROUND OF THE INVENTION

For power amplifier modules used for portable terminals or the like, further miniaturization and lower cost have been constantly demanded in response to the needs for small and low-cost portable terminals.

Further, “anywhere and anytime” communication service has expanded from a domestic market to an international market and is in transition from 2nd generation communication system to advanced 3rd generation communication system. Under these circumstances, portable terminals have to respond to necessary frequency bands and modulation schemes for respective destinations and corresponding carriers. In many cases, recent oscillators and modulators are configured as integrated circuits with commonality.

In such power amplifier modules, however, necessary characteristics are considerably different among modulation schemes, and a necessary number of semiconductor devices and matching circuits for amplification are provided to respond to two or more frequency bands, so that commonality is limited to maintain the characteristics. As a result, commonality brings fewer advantages to the power amplifier modules as compared with other components, and individual products are actually delivered for respective specifications.

The internal elements of the power amplifier module are a bias circuit, an amplifier element, a matching circuit, and a holding substrate in a simple configuration. In many cases, the foundations of the design techniques of the elements have commonalities and the elements can be replaced with one another.

Particularly when a matching circuit is configured with a lumped constant, frequency bands are likely to be handled only by changing the constant.

FIG. 11 shows a power amplifier described in Japanese Patent Laid-Open No. 2003-188664.

The power amplifier comprises a high-frequency transistor Q11, an input matching circuit 12, an output matching circuit 13, and a drain microstrip line L12. Reference numeral 14 denotes an input terminal, reference numeral C11 denotes an input coupling capacitor, reference numeral L11 denotes an input-side microstrip line, reference numeral C12 denotes an input matching capacitor, reference numeral 15 denotes a bias voltage supply terminal, reference numeral 16 denotes a drain bias supply terminal, reference numeral L12 denotes a drain microstrip line, reference numeral C14 denotes an output matching capacitor, reference numeral L14 denotes an output matching microstrip line, reference numeral C16 denotes an output coupling capacitor, and reference numeral 17 denotes an output terminal.

In the output matching circuit 13, a parallel circuit 18 comprises a microstrip line L13 divided at some midpoint and a resistor R15 connecting the divided microstrip lines L13.

High frequencies propagate as they are through a capacitor component C15 of the parallel circuit L8 and low frequencies propagate through the resistor R15. Thus, matching with a load resistance connected to the output terminal 17 can be obtained both at high frequencies and low frequencies.

In the configuration of FIG. 11, the matching range of high frequencies is limited by the microstrip line L13 and the capacitor component C15. Hence, as described in the conventional art, in order to form a power amplifier module responding to two or more frequency bands, it is necessary to design power amplifier boards dedicated to respective frequency bands while optimizing the lengths of the microstrip lines L13, which arises a problem in commonality of components.

Even if an inductor of a lumped constant component is added to correct the microstrip line L13, matching of frequency bands is optimized, and the commonality of the substrates is obtained, the price of the device and the packaging cost have to be increased contrary to the needs for low cost, resulting in an imperfect solution.

Moreover, when manufacturing a power amplifier module corresponding to two or more frequency bands, it is necessary to manufacture substrates corresponding to possible combinations, resulting in an enormous number of items and low efficiency.

An object of the present invention is to provide a high-frequency module which makes it possible to manufacture high-frequency power amplifiers for amplifying given frequency bands with a common substrate.

### DISCLOSURE OF THE INVENTION

A power amplifier module of the present invention applies a bias voltage to an output of a semiconductor device for high-frequency amplification through a first inductor and extracts an output signal from a junction point of an output of the semiconductor device for high-frequency amplification and the first inductor through a second inductor, wherein the semiconductor device for high-frequency amplification is wired with a bonding wire on a conductor pattern formed on a substrate, the semiconductor device having been fixed to the substrate, and the bonding wire from the semiconductor device for high-frequency amplification is bonded to a midpoint of a distributed constant line formed by the conductor pattern and divides the line into the first inductor and the second inductor, so that matching of handled frequencies or an output loads is performed.

With this configuration, the power amplifier module of the present invention makes it possible to arbitrarily set the length of the distributed constant line of an output matching circuit without changing the wiring of the power amplifier module substrate. Thus, it is not necessary to prepare power amplifier module substrates dedicated to a plurality of used frequency bands and output power, and the frequency bands and output power can be handled with a common substrate.

### BRIEF DESCRIPTION OF THE DRAWINGS

FIG. 1 is a circuit diagram showing a single power amplifier module according to (Embodiment 1) of the present invention;

FIG. 2 is a circuit diagram showing the power amplifier module of (Embodiment 1);

FIG. 3 is a diagram showing the front side of the substrate of the power amplifier module according to (Embodiment 1);

FIG. 4 is a diagram showing the back side of the substrate of the power amplifier module according to (Embodiment 1);

FIG. 5 is a sectional view showing the power amplifier module of (Embodiment 1);

FIG. 6 is a diagram showing the front side of the substrate when the frequency of the power amplifier module of (Embodiment 1) is switched;

FIG. 7 is a diagram showing the front side of the substrate of a power amplifier module according to (Embodiment 2) of the present invention;

FIG. 8 is a diagram showing the front side of the substrate of a power amplifier module according to (Embodiment 3) of the present invention;

FIG. 9 is a diagram showing the front side of the substrate of a power amplifier module according to (Embodiment 4) of the present invention;

FIG. 10 is a diagram showing the front side of the substrate of a power amplifier module according to (Embodiment 5) of the present invention; and

FIG. 11 shows a structural example of a conventional matching circuit.

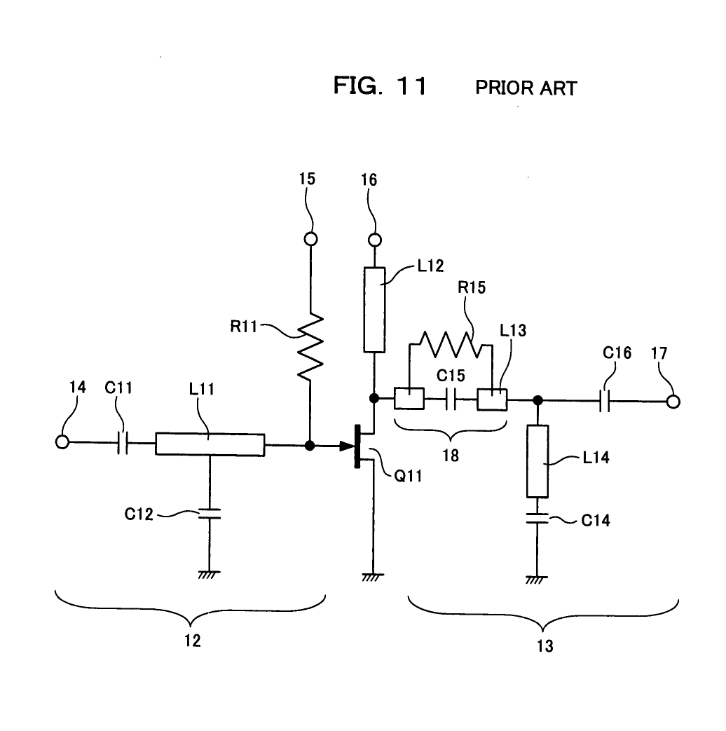

### DESCRIPTION OF THE EMBODIMENTS

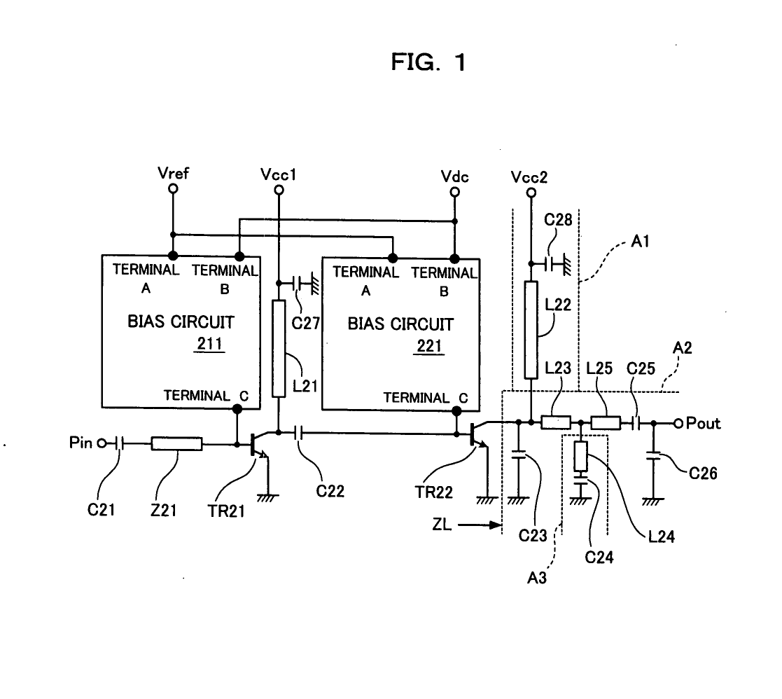

Referring to FIGS. 1 to 10, the following will describe embodiments of the present invention.

### Embodiment 1

FIGS. 1 to 6 show (Embodiment 1) of the present invention.

In this power amplifier module used for portable terminals, high-frequency amplifier circuits for respective handled frequency bands are configured on a single substrate. Since the circuits for the respective frequency bands are not different in configuration, a single high-frequency amplifier circuit will be first discussed below.

FIG. 1 shows a specific circuit example of a single power amplifier module. Illustrated electric circuits are well known as a power amplifier module in various kinds of communication equipment such as cellular phones. It is needless to say that FIG. 1 shows just one example and the power amplifier module of the present invention is not limited to the illustrated circuits.

The high-amplifier circuit of the illustrated power amplifier module includes two semiconductor devices TR21 and TR22 for a high-frequency amplification. A matching circuit, a collector bias circuit, a base bias circuit are connected to each of the semiconductor devices TR21 and TR22 for high-frequency amplification and form a circuit block.

The semiconductor devices TR21 and TR22 for high-frequency amplification each comprise a bipolar transistor. An input signal supplied from an input terminal Pin passes through a capacitor C21 and an impedance element Z21 and is supplied to the base of the semiconductor device TR21 for high-frequency amplification. The capacitor C21 and the impedance element Z21 make up a matching circuit for achieving impedance matching to an impedance (50 Ω) of an input signal line.

A signal which has been power amplified by the semiconductor device TR21 for high-frequency amplification passes through an inductor L21 making up a collector bias circuit and an impedance matching circuit comprising a capacitor C22, and the signal is supplied to the base of the semiconductor device TR22 for high-frequency amplification.

A signal which has been power amplified by the semiconductor device TR22 for high-frequency amplification passes through a second harmonic countermeasure unit A3 comprising a capacitor C23, an inductor L23, an inductor L24, and a capacitor C24 and an output matching unit A2 comprising an inductor L25, a capacitor C25, and a capacitor C26. The signal is then supplied to an output terminal Pout and outputted therefrom.

A bias circuit 211 connected to the semiconductor device TR21 for high-frequency amplification has terminals A, B, and C. When a control voltage is applied to the terminal A and a direct-current power supply is applied to the terminal B, a direct-current voltage and current obtained by controlling, through the terminal A, the direct-current power supply having been applied to the terminal B is outputted to the terminal C. The terminal A is connected to a Vref terminal, the terminal B is connected to a Vdc terminal, and the terminal C is connected to the base of the semiconductor device TR21 for high-frequency amplification and supplies a bias.

A bias circuit 221 connected to the semiconductor device TR22 for high-frequency amplification is similar to the bias circuit 211 and has a terminal A connected to the Vref terminal, a terminal B connected to the Vdc terminal, and a terminal C which is connected to the base of the semiconductor device TR22 for high-frequency amplification and supplies a bias.

As described above, one end of the inductor L21 making up the collector bias circuit is connected to the collector end of the semiconductor device TR21 for high-frequency amplification, and the other end of the inductor L21 is connected to a first power supply terminal Vcc1 and one end of a capacitor C27. The other end of the capacitor C27 is grounded.

As described above, one end of an inductor L22 making up a collector bias circuit is connected to the collector end of the semiconductor device TR22 for high-frequency amplification, and the other end of the inductor L22 is connected to a second power supply terminal Vcc2 and one end of a capacitor C28. The other end of the capacitor C28 is grounded.

The output matching unit A2 is a circuit for impedance matching in a frequency band (fundamental) to be amplified in a frequency band handled by the power amplifier module, e.g., a frequency band of 1750 to 1770 MHz. One end of the inductor L23 and the capacitor C23 having the other end grounded are connected to the collector terminal of the semiconductor device TR22 for high-frequency amplification. The other end of the inductor L23 is connected to one end of the inductor L25 and the inductor L24 included in the second harmonic countermeasure unit A3. The other end of the inductor L25 is connected to one end of the capacitor C25, and the other end of the capacitor C25 is connected to an output terminal Pout and the capacitor C26 having the other end grounded.

When a frequency other than the fundamental is transmitted, communication equipment degrades its characteristic. Therefore, the second harmonic countermeasure unit A3 prevents a second harmonic component from being transmitted to output. Hence, the impedance of a circuit comprising the inductor L24 and the capacitor C24 is designed such that an impedance ZL is 0 at a second harmonic frequency when viewing the output terminal Pout from the collector terminal of the semiconductor device TR22 for high-frequency amplification.

The bias circuit and a collector bias unit A1 are provided for applying a direct-current bias to the semiconductor device TR22 for high-frequency amplification to cause the semiconductor device TR22 for high-frequency amplification to act as an amplifier. For example, a signal of f=1750 MHz and P=16 dBm is inputted to the base terminal while 1.3 V is supplied to the base, a direct-current voltage of 3.5 V is supplied to the collector bias terminal, and a direct current of 400 mA is applied. In this case, the collector terminal has a signal of 28 dBm and the semiconductor device TR22 for high-frequency amplification has an amplification of 12 dB.

In the bias circuit and the collector bias unit A1, a direct-current bias is applied to the semiconductor device TR22 for high-frequency amplification, and the inductor L22 comprises a microstrip line (conductor pattern) having a pattern length of (λ/4) and is connected to the grounded capacitor C28 in order to prevent a signal from leaking to the outside.

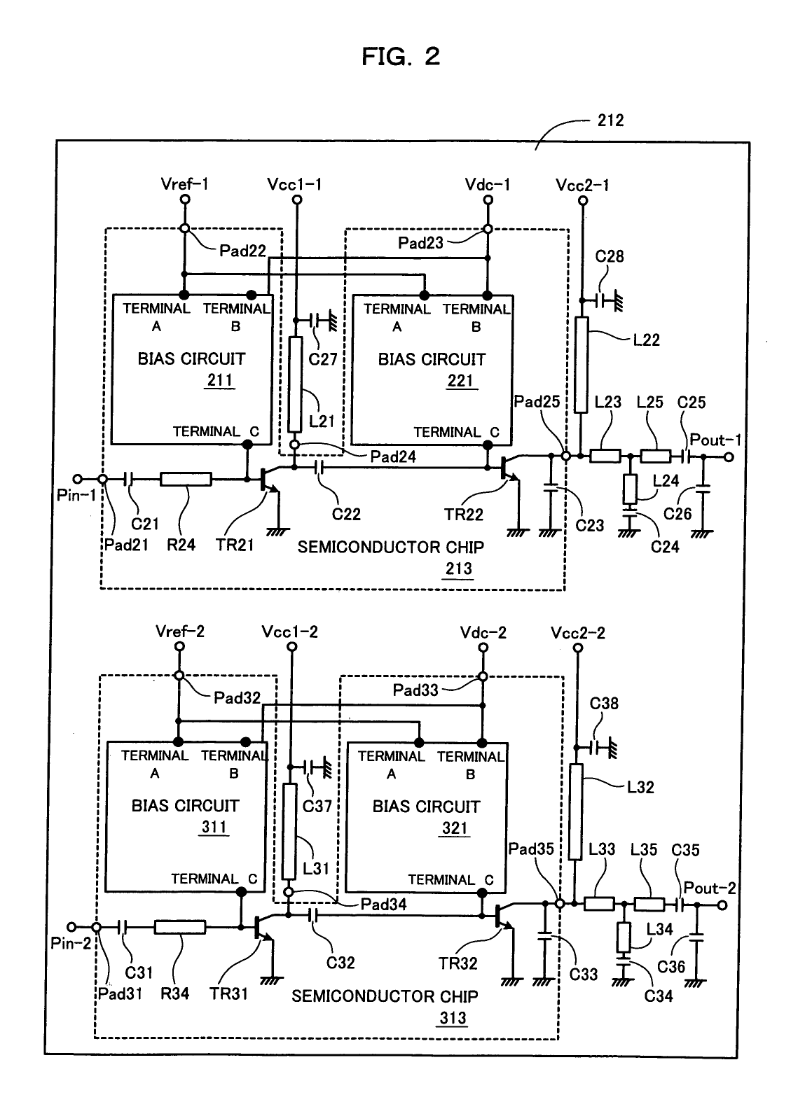

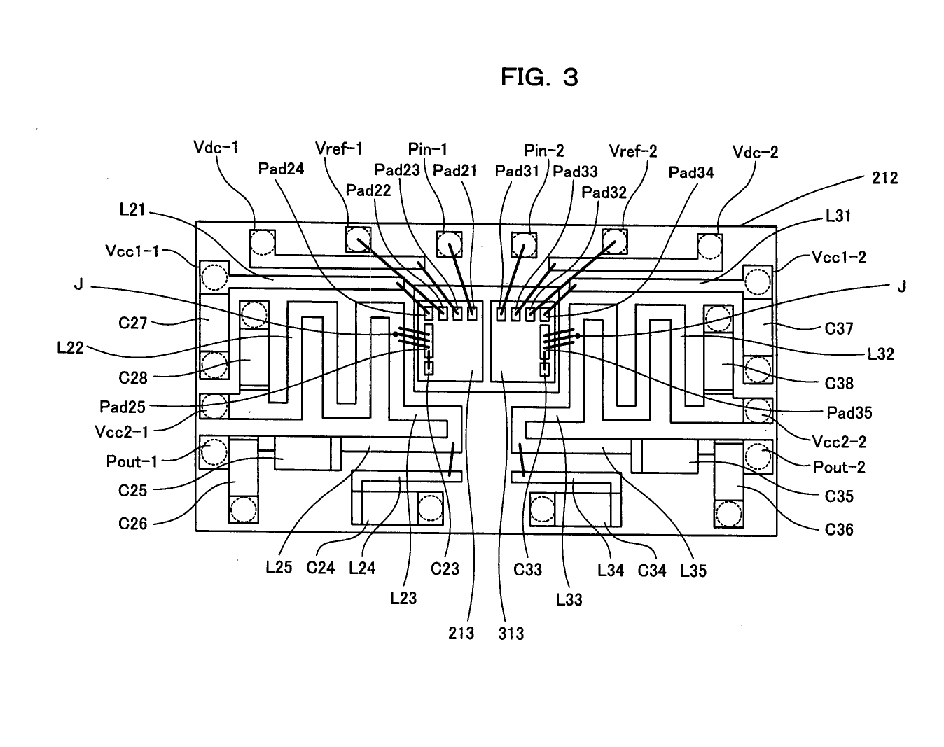

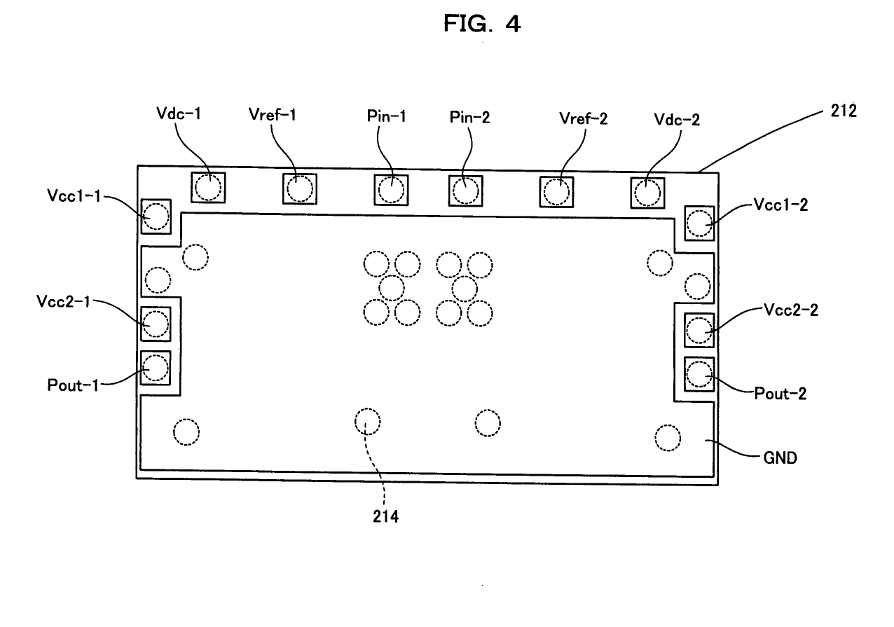

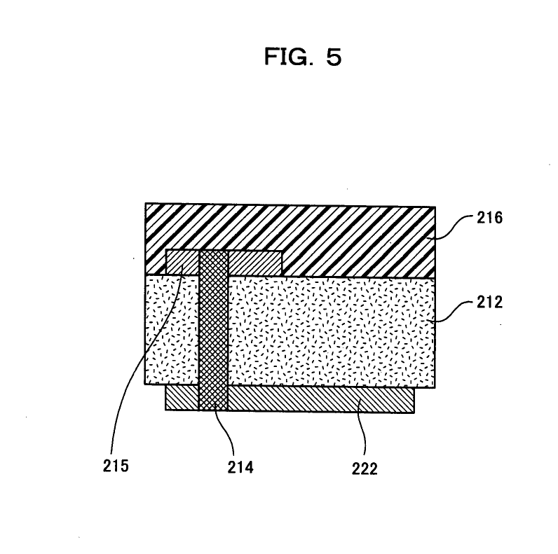

FIG. 2 is a circuit diagram showing the power amplifier module in which two high-frequency amplifier circuits of FIG. 1 are configured for respective handled frequency bands on a single substrate. FIG. 3 is diagram showing the front side of the substrate of the power amplifier module shown in FIG. 2. FIG. 4 is diagram showing the back side of the substrate of the power amplifier module shown in FIG. 2. FIG. 4 is also a perspective view taken from component surface shown in FIG. 3. FIG. 5 is a sectional view showing the substrate of the power amplifier module shown in FIG. 2.

Referring to FIGS. 2 to 5, the power amplifier module will be specifically described below.

The power amplifier module includes the two power amplifier circuits shown in FIG. 1 and has a dielectric substrate 212, a semiconductor chip 213, a semiconductor chip 313, and capacitors C24, C26, C27, C28, C34, C36, C37, and C38.

The dielectric substrate 212 has a conductor pattern 215 on its front side and a conductor pattern 222 on its back side. The conductor pattern 215 and the conductor pattern 222 are connected to each other via through holes 214.

The illustrated dielectric substrate 212 is a single layer but is not particularly limited. A multilayer structure with a plurality of layers may be used.

The dielectric substrate 212 has the semiconductor chip 213, the semiconductor chip 313, and the capacitors C24, C26, C27, C28, C34, C36, C37, and C38 which are included in the circuit diagram of FIG. 2. Further, the inductors L21, L22, L23, L24, L25, L31, L32, L33, L34, and L35 are formed by the conductor pattern 215 on the front side and are connected to have a necessary circuit configuration.

On the dielectric substrate 212, signal input terminals Pin-1 and Pin-2, signal output terminals Pout-1 and Pout-2, aground terminal GND, and power supply terminals Vref-1, Vref-2, Vdc-1, Vdc-2, Vcc1-1, Vcc1-2, Vcc2-1, Vcc2-2 are formed as electrode patterns by the conductor pattern 222 on the back side of the dielectric substrate 212.

The semiconductor chip 213 and the semiconductor chip 313 are microwave monolithic ICs (MMICs). In the circuit diagram of FIG. 2, the semiconductor chip 213 includes the bias circuit 211, the bias circuit 221, the capacitors C21, C22, and C23, and the impedance element Z21. The semiconductor chip 213 is connected to the conductor pattern 215 on the dielectric substrate 212 via pads Pad 21 to Pad 25 through bonding wires.

For the GNDs of the elements included in the semiconductor chip 213, the back side of the semiconductor chip 213 and the conductor pattern 215 are connected to each other with a conductive adhesive such as silver paste.

The semiconductor chip 313 has a similar configuration. The semiconductor chip 313 includes a bias circuit 311, a bias circuit 321, capacitors C31, C32, and C33, and an impedance element Z31. The semiconductor chip 313 is connected to the conductor pattern 212 via pads Pad 31 to Pad 35 through bonding wires. For the GNDs of the elements included in the semiconductor chip 313, the back side of the semiconductor chip 313 and the conductor pattern 215 are connected to each other with a conductive adhesive such as silver paste.

In order to obtain reliability, the semiconductor chip 213 and the semiconductor chip 313 are mounted while being sealed with a sealing resin 216.

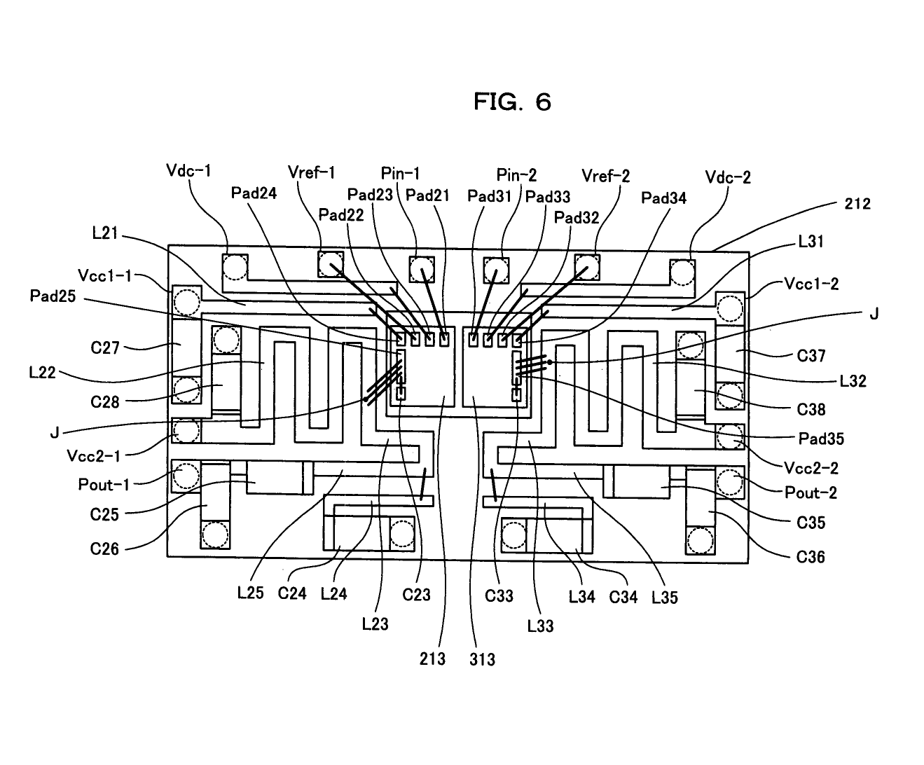

The inductor L23 included in the output matching unit A2 and the inductor L22 included in the collector bias unit A1 are made up of a single microstrip line. The inductors L22 and L23 are divided at a bonding position J of the bonding wire for connecting to the collector terminal of the semiconductor device TR22 for high-frequency amplification. The foregoing explanation described the side of the semiconductor chip 213. The side of the semiconductor chip 313 has a similar configuration. The inductor L33 included in the output matching unit A2 and the inductor L32 included in the collector bias unit A1 are made up of a single microstrip line. The inductors L32 and L33 are divided at a bonding position J of the bonding wire for connecting to the collector terminal of the semiconductor device TR32 for high-frequency amplification. FIG. 6 shows that a handled frequency of the semiconductor chip 213 is switched.

With this configuration, only by changing the bonding position J of the bonding wire, the inductance value of the inductor L23 and the inductance value of the inductor L33 can be arbitrarily changed.

Since optimization is performed to a given frequency band according to the length of the inductor L23, the lengths of the inductors L22 and L32 are changed according to frequency bands. In actual use, matching hardly varies with the lengths of the inductors L22 and L32 and the variation is absorbed by changing the constants of other elements. Thus, sufficient lengths are not always necessary.

The arrangement of the other circuit components is not particularly limited. FIGS. 3, 4, and 5 show just one example. In this example, the capacitor comprises a chip component and is mounted by soldering or the like. For example, the dielectric substrate may have a multilayer structure and may be formed by conductor patterns between layers.

The following shows an actual matching constant according to a simulation result. In the case where the dielectric substrate 212 has a thickness of 160 μm and a relative permittivity of 4.07 and the width of the microstrip line is 0.15 mm, when the capacitors have the following capacitances and the inductors have the following lengths: C23=2.6 pF, C24=1.8 pF, C25=5 pF, C26=2 pF, L22=12 mm, L23=2.8 mm, L24=1.5 mm, and L25=0.9 mm, a semiconductor device TR23 for high-frequency amplification has a load impedance of 3.3 to 2.0 j at a frequency of 1980 MHz.

For a frequency of 1750 MHz, when L23=3.5 mm, L22=11.3 mm, and C26=2.7 pF are set, the semiconductor device TR23 for high-frequency amplification has a load impedance of 3.3 to 2.0 j.

In this way, a frequency band can be changed by changing bonding and the capacitances of the capacitors, so that two or more frequency bands can be handled without changing the pattern of the substrate.

### Embodiment 2

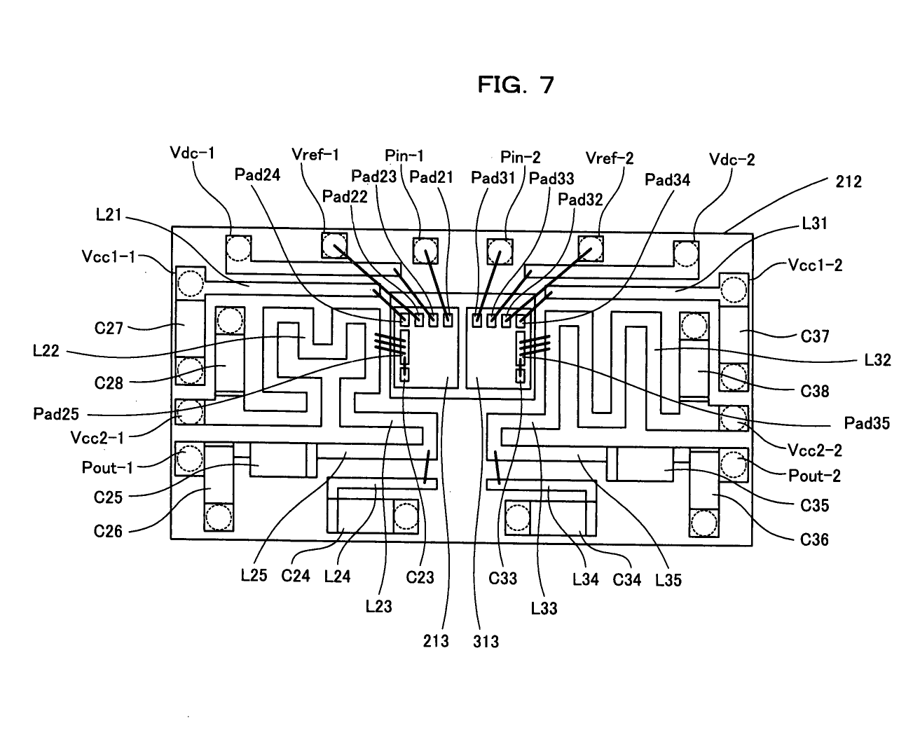

FIG. 7 shows a power amplifier module in which two high-frequency amplifier circuits for respective handled frequency bands are configured on a single substrate. (Embodiment 2) is identical to (Embodiment 1) of FIG. 3 except for a ratio of the lengths of inductors L22 and L23 formed by a conductor pattern. Different frequency bands and different output levels can be handled by changing a ratio of the inductor L22 and the inductor L23 and the sum of the lengths of the inductor L22 and the inductor L23.

The following shows an actual matching constant according to a simulation result.

In the case where a dielectric substrate 212 has a thickness of 160 μm and a relative permittivity of 4.07 and the width of the microstrip line is 0.15 mm, when the capacitors have the following capacitances and the inductors have the following lengths: C23=3.6 pF, C24=9.8 pF, C25=1000 pF, C26=1.85 pF, L22=9.25 mm, L23=5.55 mm, L24=1.5 mm, and L25=0.9 mm, a semiconductor device TR23 for high-frequency amplification has a load impedance of 3.9 to 0.2 j at a frequency of 810 MHz. For a frequency of 920 MHz, when L23=4.55 mm, L22=10.25 mm, and C26=0.5 pF are set, the semiconductor device TR23 for high-frequency amplification has a load impedance of 3.1 to 0.2 j.

The impedance of a real part is changed to respond to the change of a load output level. In this way, a frequency band and an output level can be changed by changing bonding and the capacitances of the capacitors, so that two or more frequency bands can be handled without changing the pattern of the substrate.

### Embodiment 3

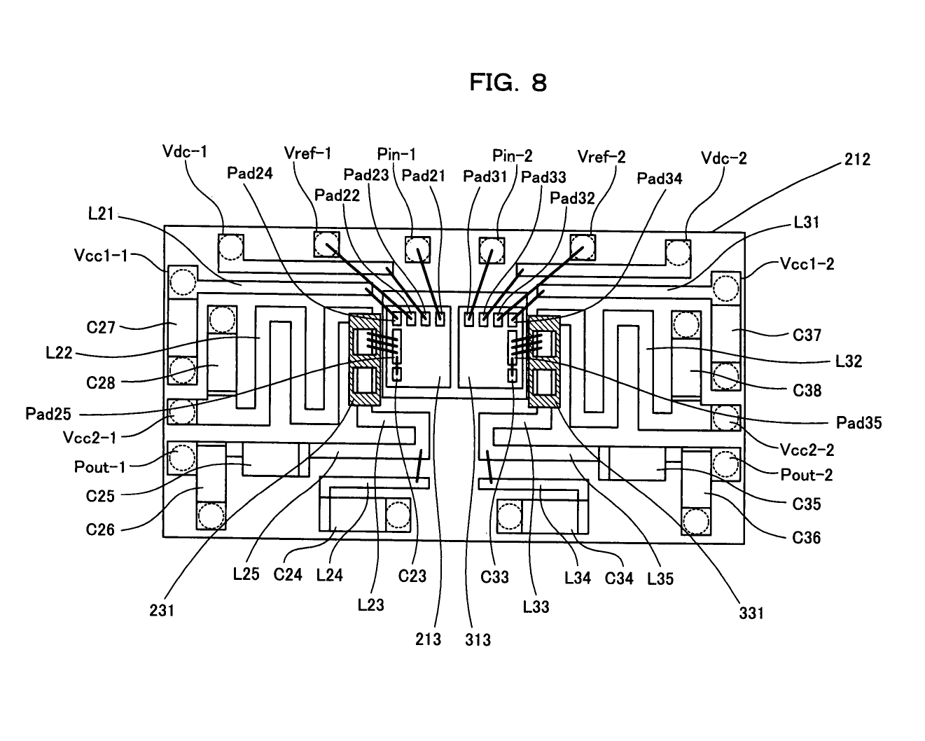

FIG. 8 shows a power amplifier module in which two high-frequency amplifier circuits for respective handled frequency bands are configured on a single substrate. (Embodiment 3) is different from (Embodiment 1) of FIG. 3 only in the following points: in order to mark out a bonding position J for dividing, through bonding, inductors L22 and L23 formed by a conductor pattern, a portion surrounding the bonding position J is covered with a resist 231, and in order to mark out a bonding position J for dividing inductors L32 and L33 through bonding, a portion surrounding the bonding position J is covered with a resist 331, so that a given frequency or output level can be easily set.

The resists 231 and 331 are just illustrated as examples. The materials of the resists and a shape for marking out the bonding position are not limited to those of FIG. 8.

### Embodiment 4

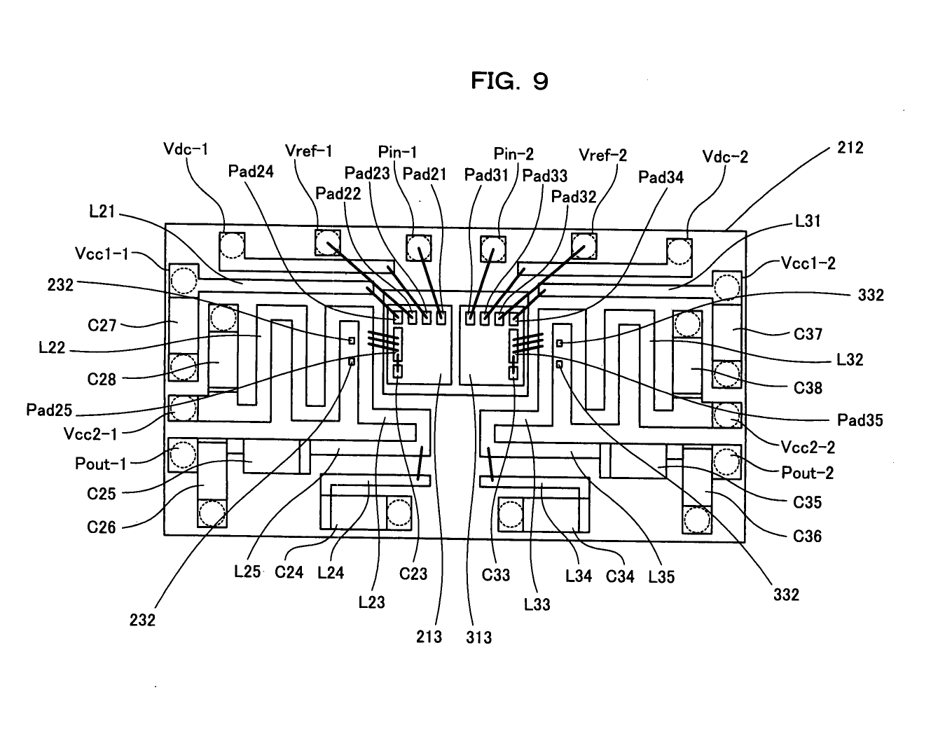

FIG. 9 shows a power amplifier module in which two high-frequency amplifier circuits for respective handled frequency bands are configured on a single substrate. (Embodiment 4) is different from (Embodiment 1) of FIG. 3 only in the following points: in order to mark out a bonding position J for dividing, through bonding, inductors L22 and L23 formed by a conductor pattern, marks 232 are provided on a portion surrounding the bonding position J, and in order to mark out a bonding position J for dividing, through bonding, inductors L32 and L33 formed by a conductor pattern, marks 332 are provided on a portion surrounding the bonding position J, so that a given frequency or output level can be easily set.

The marks 232 and 332 are just illustrated as examples. The shapes and positions of the marks are not particularly limited. During the formation of the substrate, the marks 232 and 332 can be formed by a conductor pattern.

### Embodiment 5

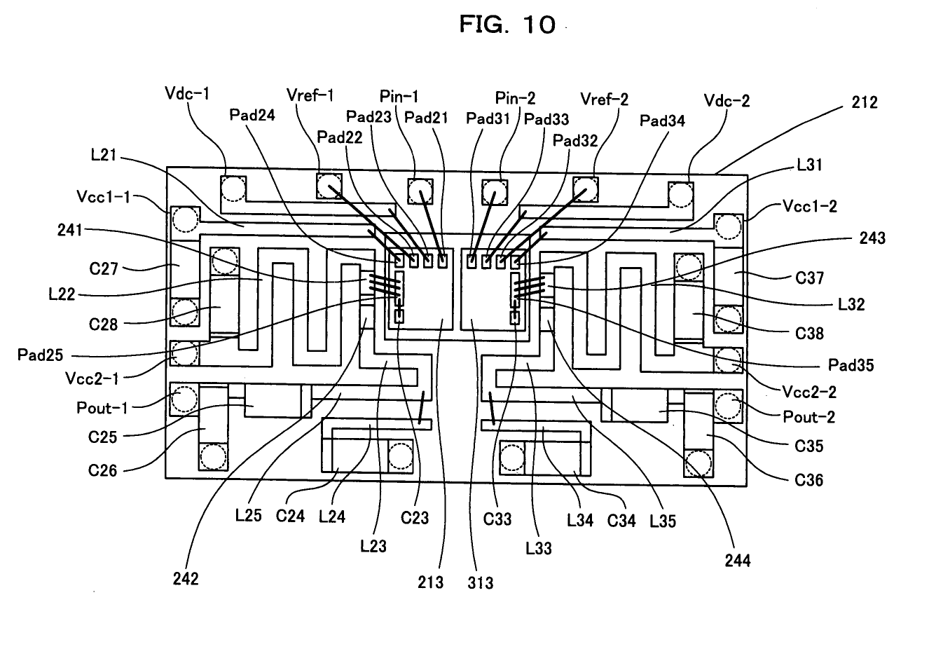

FIG. 10 shows a power amplifier module in which two high-frequency amplifier circuits for respective handled frequency bands are configured on a single substrate. (Embodiment 5) is different from (Embodiment 1) of FIG. 3 only in the following points: in order to mark out a bonding position J for dividing, through bonding, inductors L22 and L23 formed by a conductor pattern, bumps 241 and 242 are formed by plating or the like on the conductor pattern of the bonding position J, and in order to mark out a bonding position J for dividing, through bonding, inductors L32 and L33 formed by a conductor pattern, bumps 243 and 244 are formed by plating or the like on the conductor pattern of the bonding position J, so that a given frequency or output level can be easily set.

The bumps 241, 242, 243, and 244 are just illustrated as examples. The shapes and positions of the bumps are not particularly limited.

With this configuration, a power amplifier module having two or more high-frequency power amplifier circuits for amplifying given frequency bands can be manufactured with a common substrate.

The power amplifier module of the present invention makes it possible to manufacture, with a common substrate, the configuration having the two or more high-frequency power amplifiers for amplifying given frequency bands, thereby achieving low-cost portable terminals with higher productivity.

What is claimed is:

1. A power amplifier module for applying a bias voltage to an output of a semiconductor device for high-frequency amplification through a first inductor and extracts an output signal from a junction point of an output of the semiconductor device for high-frequency amplification and the first inductor through a second inductor, wherein
the semiconductor device for high-frequency amplification is wired with a bonding wire on a conductor pattern formed on a substrate, the semiconductor device having been fixed to the substrate, and
the bonding wire from the semiconductor device for high-frequency amplification is bonded to a midpoint of a distributed constant line formed by the conductor pattern and divides the line into the first inductor and the second inductor, so that matching of a handled frequency or an output load is performed.

2. The power amplifier module according to claim 1, wherein a portion around a bonding position is covered with a resist or a resin material.

3. The power amplifier module according to claim 1, wherein the substrate has a mark or bump corresponding to a bonding position.

4. The power amplifier module according to claim 1, further comprising high-frequency amplifier circuits with different handled frequencies on the single substrate.

5. The power amplifier module according to claim 1, wherein the substrate has a mark formed by the conductor pattern, the mark corresponding to a bonding position.
